(19) United States
(12) Patent Application Publication
(10) Pub. No.: US 2022/0276295 A1
(43) Pub. Date: Sep. 1, 2022

(54) LEAKAGE ELECTRIC FIELD MEASUREMENT DEVICE

(71) Applicant: Panasonic Intellectual Property Management Co., Ltd., Osaka (JP)

(72) Inventors: Ryo MATSUBARA, Osaka (JP); Shinichi TANIMOTO, Kyoto (JP)

(73) Assignee: Panasonic Intellectual Property Management Co., Ltd., Osaka (JP)

(21) Appl. No.: 17/637,316

(22) PCT Filed: Aug. 18, 2020
(86) PCT No.: PCT/JP2020/031063

§ 371 Date: Feb. 22, 2022

(30) Foreign Application Priority Data
Aug. 30, 2019 (JP) 2019-159101

(51) Int. Cl. G01R 29/12; G06T 11/00

(52) U.S. Cl. CPC G01R 29/12; G06T 11/00

(57) ABSTRACT

A leakage electric field measurement device includes a first acquirer that measures an intensity of a leakage electric field, a second acquirer that measures a distance to at least one target object, a third acquirer that acquires a captured image of the at least one target object, and a controller that generates a composite image in which a measurement result of the intensity of the leakage electric field measured by the first acquirer and a measurement location corresponding to a shortest distance among distances measured by the second acquirer are superimposed on the captured image acquired by the third acquirer.

### TECHNICAL FIELD

The present disclosure relates to a leakage electric field measurement device.

### BACKGROUND ART

PTL 1 discloses a safety zone checking system that displays and prints out a safety zone for performing maintenance inspection or construction of a plant such as a substation. This safety zone checking system is provided with means for obtaining display and print output in a three-dimensional model of an apparatus in which a charge/power failure state or an operation/stop state of the apparatus is color-coded from an apparatus operation procedure of a plant and apparatus status data and apparatus connection data.

### CITATION LIST

### Patent Literature

PTL 1: Japanese Patent Unexamined Publication No. 10-198877

### SUMMARY OF THE INVENTION

The present disclosure has been made in view of the above circumstances of the related art, and an object thereof is to provide a leakage electric field measurement device that visualizes a direction in which a leakage electric field is generated.

According to the present disclosure, there is provided a leakage electric field measurement device including a first acquirer that measures an intensity of a leakage electric field; a second acquirer that measures a distance to at least one target object; a third acquirer that acquires a captured image of the at least one target object; and a controller that generates a composite image in which a measurement result of the intensity of the leakage electric field measured by the first acquirer and a measurement location corresponding to a shortest distance among distances measured by the second acquirer are superimposed on the captured image acquired by the third acquirer.

According to the present disclosure, it is possible to visualize a direction in which a leakage electric field is generated.

### BRIEF DESCRIPTION OF DRAWINGS

FIG. 1 is an appearance diagram illustrating an example of a leakage electric field measurement device (rear surface) according to Exemplary Embodiment 1.

FIG. 2 is an appearance diagram illustrating an example of the leakage electric field measurement device (front surface) according to Exemplary Embodiment 1.

FIG. 3 is a block diagram illustrating an internal configuration example of the leakage electric field measurement device according to Exemplary Embodiment 1.

FIG. 4 is a flowchart illustrating an operation procedure example of the leakage electric field measurement device according to Exemplary Embodiment 1.

FIG. 5A is a diagram illustrating a measurement example of a leakage electric field by a measurement unit.

FIG. 5B is a diagram illustrating a display example of a superimposition image.

FIG. 6 is an appearance diagram illustrating an example of a leakage electric field measurement device (rear surface) according to Exemplary Embodiment 2.

FIG. 7 is an appearance diagram illustrating an example of the leakage electric field measurement device (front surface) according to Exemplary Embodiment 2.

FIG. 8 is a block diagram illustrating an internal configuration example of the leakage electric field measurement device according to Exemplary Embodiment 2.

### DESCRIPTION OF EMBODIMENTS

### Background of Details of Exemplary Embodiment 1

In the safety zone checking system in PTL 1, there is a probability that a charge/power failure state or an operation/stop state of the apparatus displayed and printed out by the three-dimensional model may not match an actual charge/power failure state or operation/stop state of the apparatus due to an abnormality such as a connection failure of the apparatus. The safety zone checking system does not report a charging or operation state of an apparatus installed around a worker (hereinafter, referred to as a user) who performs maintenance inspection or construction of a plant such as a substation. Therefore, it is difficult for the user to recognize a charging or operation state of surrounding apparatuses during the work, and there is a possibility that an electric shock may occur during the work.

It is preferable that the user checks a generation source of a leakage electric field such as an apparatus that is charged or in operation in the surroundings or an apparatus that uses a high voltage as a power source, not only during work, but since an energized state of these apparatus cannot be visually checked, a direction of the generation source of the leakage electric field (that is, an arrival direction of the leakage electric field) is not known. A frequency of the electric field leaking from these apparatuses (energized state) is 50 Hz to 60 Hz, which is highly distance-dependent. Therefore, in a case where an omnidirectional antenna is used, a direction of a generation source of the leakage electric field (that is, an arrival direction of the leakage electric field) is difficult to specify or estimate. Therefore, it is difficult for a user to know a direction of a generation source of the leakage electric field (that is, an arrival direction of the leakage electric field).

Therefore, in each of the following exemplary embodiments, an example of a leakage electric field measurement device that visualizes a direction in which a leakage electric field is generated will be described.

Hereinafter, exemplary embodiments in which a configuration and an operation of the leakage electric field measurement device according to the present disclosure are specifically disclosed will be described in detail with reference to the drawings as appropriate. However, more detailed description than necessary may be omitted. For example, detailed description of already well-known matters and repeated description of substantially the same configuration may be omitted. This is to avoid unnecessary redundancy of the following description and to facilitate the understanding of those skilled in the art. The accompanying drawings and the following description are provided for those skilled in the art to fully understand the present disclosure, and are not intended to limit the subject matter described in the claims.

### Exemplary Embodiment 1

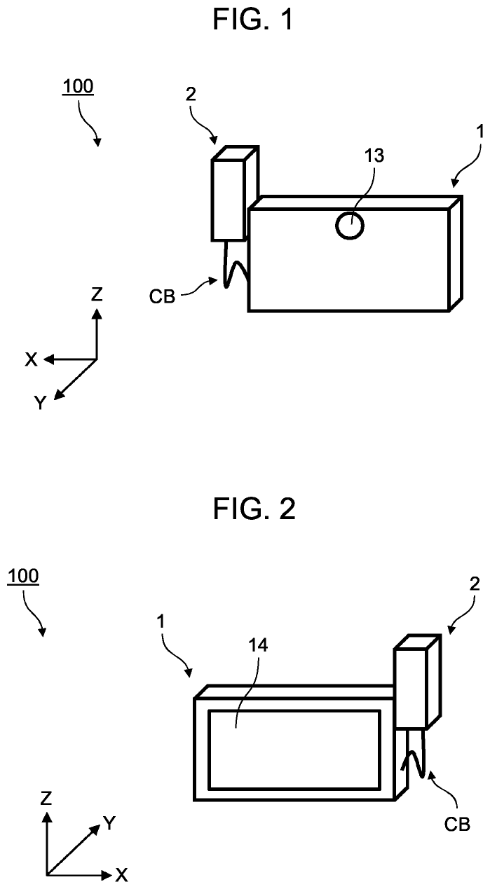

First, an appearance of leakage electric field measurement device 100 according to Exemplary Embodiment 1 will be described with reference to FIGS. 1 and 2. FIG. 1 is an appearance diagram illustrating an example of the leakage electric field measurement device (rear surface) according to Exemplary Embodiment 1. FIG. 2 is an appearance diagram illustrating an example of the leakage electric field measurement device (front surface) according to Exemplary Embodiment 1. A Y direction illustrated in FIGS. 1 and 2 indicates a front-rear direction of leakage electric field measurement device 100 and terminal device 1, and the rear surface is located in the +Y direction and the front surface is located in the −Y direction. An X direction indicates a longitudinal direction of leakage electric field measurement device 100 and terminal device 1. A Z direction indicates a height direction of leakage electric field measurement device 100 and terminal device 1. The X direction indicates a transverse direction in a case where leakage electric field measurement device 100 and terminal device 1 illustrated in FIGS. 1 and 2 are used in a state of being rotated by 90°.

Leakage electric field measurement device 100 has a configuration in which terminal device 1 such as an augmented reality wearable computer such as a so-called tablet PC, a smartphone, or a smart glass is connected to measurement unit 2 capable of measuring a leakage electric field via a USB (Universal Serial Bus) cable CB in a wired manner. A cable used for connection is not limited to USB cable CB, and may be, for example, a local area network (LAN) cable.

Leakage electric field measurement device 100 includes camera 13 on the rear surface side of terminal device 1 and monitor 14 on the front surface side. Leakage electric field measurement device 100 measures a leakage electric field that leaks from a measurement target object (for example, a conductor such as an electric wire, a switch, an electrical/electronic apparatus) which is in a live wire (energized) state and to which an AC voltage having a frequency of 50 Hz to 60 Hz is applied. Positions of camera 13 and monitor 14 illustrated in FIGS. 1 and 2 are examples, and, for example, in a case where terminal device 1 is an augmented reality wearable computer, needless to say, positions thereof are not limited to these.

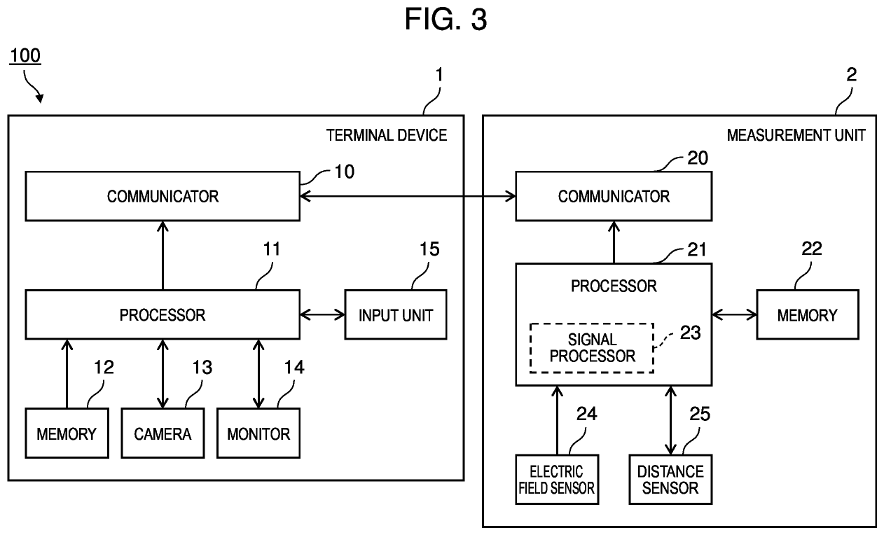

FIG. 3 is a block diagram illustrating an internal configuration example of leakage electric field measurement device 100 according to Exemplary Embodiment 1. Leakage electric field measurement device 100 includes terminal device 1 and measurement unit 2.

First, an internal configuration example of terminal device 1 will be described. Terminal device 1 is configured to include communicator 10, processor 11, memory 12, camera 13, monitor 14, and input unit 15. In a case where terminal device 1 is implemented by an augmented reality wearable computer, camera 13 is not an essential constituent and may thus be omitted, or may be configured separately from terminal device 1 instead of being integrated with terminal device 1. Monitor 14 may be configured separately from terminal device 1 instead of being integrated with terminal device 1.

Communicator 10 has a USB connector (not illustrated) or a LAN connector, and is communicatively connected to communicator 20 in measurement unit 2 in a wired manner by using USB cable CB or a LAN cable (not illustrated). Communicator 10 outputs measurement results such as a leakage electric field value and a distance between the measurement target object in which a leakage electric field is detected, received from communicator 20, to processor 11.

In a case where each of electric field sensor 24 and distance sensor 25 of measurement unit 2 is provided separately, communicator 10 may be communicatively connected to each of electric field sensor 24 and distance sensor 25 by using each of a plurality of USB cables (not illustrated).

Communicator 10 may be wirelessly communicatively connected to communicator 20. The wireless communication referred to here is communication via, for example, short-range wireless communication such as Bluetooth (registered trademark) or NFC (registered trademark), or a wireless LAN such as Wifi (registered trademark).

Processor 11 as an example of a controller is configured by using, for example, a central processing unit (CPU), a digital signal processor (DSP), or a field programmable gate array (FPGA), and controls an operation of each constituent of terminal device 1. Processor 11 cooperates with memory 12 to perform various processes and control in an integrated manner. Specifically, processor 11 refers to a program and data stored in memory 12 and executes the program to realize a function of each constituent (for example, a function of determining whether or not a measured leakage electric field exceeds a set threshold value, and a function of outputting a composite image in which a measurement result is superimposed on a captured image acquired by camera 13 to monitor 14).

Processor 11 stores a threshold value related to a leakage electric field intensity input by a user in memory 12. Processor 11 starts measurement of a leakage electric field intensity, a distance to a measurement target object, and a direction of the target object with the user's input operation for starting the measurement as a trigger. The threshold value related to the leakage electric field intensity and the input operation for starting the measurement are received by input unit 15, and an input result is input to processor 11.

Processor 11 receives each of measurement results including a leakage electric field intensity measured by electric field sensor 24 and a distance to and a direction of a generation source of the leakage electric field measured by distance sensor 25 via communicator 10.

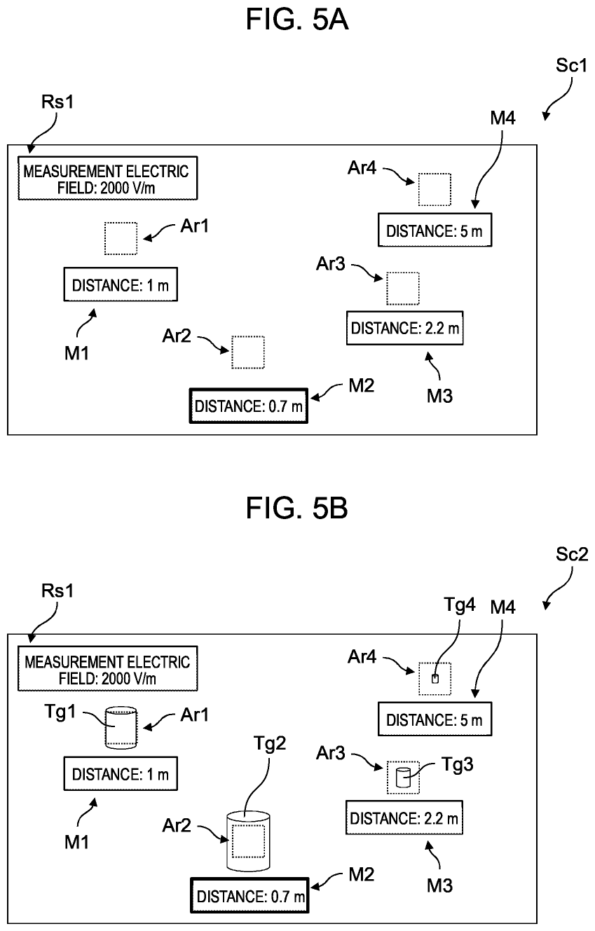

Processor 11 receives a captured image acquired by camera 13. Processor 11 may receive a captured image acquired by distance sensor 25. Processor 11 generates a composite image (refer to FIG. 5B) in which each received measurement result is superimposed on the captured image acquired by camera 13. Specifically, processor 11 superimposes information regarding the leakage electric field intensity measured by electric field sensor 24 (hereinafter, referred to as a measurement electric field) on the captured image. Processor 11 superimposes, on the captured image, distance information to the generation source of the leakage electric field measured by distance sensor 25 and a frame line indicating a position of the generation source (that is, a measurement target object) of the leakage electric field estimated from the distance and the direction. Processor 11 outputs a composite image generated by superimposing the information and the frame line on the captured image to monitor 14.

The frame line indicating the position of the measurement target object may be simply a leakage electric field value (numerical value) or distance information which is a measurement result of the leakage electric field intensity. Here, the leakage electric field value (numerical value) is superimposed at a position near a measurement target object to which a measured distance is shortest. The distance information is superimposed at a position near a measurement target object to which a distance is measured. Consequently, the user can check the position of the measurement target object on the basis of the position on which the leakage electric field value (numerical value) or the distance information is superimposed, and check the leakage electric field value leaking from the measurement target object or the distance to the measurement target object.

Electric field sensor 24 constantly receives a signal based on the leakage electric field within a signal receivable range of electric field sensor 24. Distance sensor 25 sequentially executes measurement of distances and directions to one or more generation sources of leakage electric fields within a measurable range of distance sensor 25. Therefore, processor 11 superimposes measurement electric fields, distance information, and frame lines on the captured image on the basis of respective measurement results sequentially received, and thus generates a composite image.

Processor 11 compares the measurement electric field that is measured by electric field sensor 24 with the threshold value set by the user. In a case where the measurement electric field exceeds the threshold value, processor 11 emphasizes and displays distance information or a frame line of a generation source (measurement target object) of the leakage electric field located at the shortest distance among the one or more measurement results received from distance sensor 25. Consequently, leakage electric field measurement device 100 can visualize a direction of a leakage electric field generated at the shortest distance. Leakage electric field measurement device 100 emphasizes and displays a measurement target object located at the shortest distance to the user or a distance to the measurement target object, and can thus visualize and present, to the user, a direction in which a live wire or an energized object emitting a high leakage electric field is present.

Processor 11 does not have to superimpose the distance information on the captured image. In a case where each of a plurality of pieces of distance information is received, processor 11 may superimpose only distance information regarding one measurement target object located at the shortest distance among the pieces of distance information regarding a plurality of respective measurement target objects.

Processor 11 may compare the received measurement electric field with the threshold value, and change an emphasis method according to a comparison result. For example, processor 11 may display a frame line red in a case where the measurement electric field exceeds the threshold value, and may display a frame line blue in a case where the measurement electric field is below the threshold value. Processor 11 may change a leakage electric field value, a character color of the distance information, or a color of the frame line according to a comparison result.

Memory 12 includes, for example, a random access memory (RAM) as a work memory used when each process of processor 11 is executed and a read only memory (ROM) that stores programs and data defining an operation of processor 11. Data or information generated or acquired by processor 11 is temporarily stored in the RAM. A program defining an operation of processor 11 is written in the ROM. Memory 12 stores a set threshold value of a leakage electric field intensity, emphasis and display methods, an offset amount between an imaging region of camera 13 and a measurement range of measurement unit 2, and the like.

The offset amount referred to here is a difference between a predetermined position (coordinates) in an imaging region imaged by camera 13 and a predetermined position (coordinates) in a measurement range measured by measurement unit 2. Specifically, the offset amount is a difference between a reference point in the imaging region of camera 13 (for example, a center point of the imaging region) and a reference point in the measurement range of measurement unit 2 (for example, a center point of the measurement range). Processor 11 executes a position alignment process of aligning a predetermined position (coordinates) in the measurement range with a position (coordinate) corresponding to a predetermined position (coordinate) in the corresponding imaging region on the basis of the offset amount, and generates a composite image. This position alignment process may be realized by, for example, a well-known technique.

Camera 13 as an example of a second acquirer and a third acquirer is configured to include at least a lens (not illustrated) and an image sensor (not illustrated). The image sensor is, for example, a solid-state imaging sensor such as a charged-coupled device (CCD) or a complementary metal oxide semiconductor (CMOS), and converts an optical image formed on an imaging surface into an electric signal.

Camera 13 is provided on the rear surface side of terminal device 1. A position where camera 13 is provided is not limited to the position illustrated in FIG. 1. For example, camera 13 may be provided at the center position on the rear surface side of terminal device 1. Camera 13 has a function of executing image analysis and executing a so-called autofocus process of automatically focusing on a predetermined measurement target object captured in the imaging region. Camera 13 executes the autofocus process on the measurement target object captured in the imaging region, and measures a distance to the measurement target object on the basis of a focal length when the measurement target object is in focus. Camera 13 outputs the acquired captured image and information regarding the measured distance to the measurement target object to processor 11.

In a case where it is determined through image analysis that a plurality of measurement target objects are captured in the imaging region, camera 13 sequentially executes the autofocus process on each of the plurality of measurement target objects. Camera 13 measures a distance to each of the plurality of measurement target objects on the basis of the focal length.

In a case where the user has designated a measurement target object, camera 13 executes the autofocus process on the designated measurement target object on the basis of a control signal input from processor 11.

Monitor 14 as an example of an output unit is configured by using, for example, a liquid crystal display (LCD) or an organic electroluminescence (EL). Monitor 14 displays the captured image acquired by camera 13 or the composite image generated by processor 11.

Monitor 14 may be a touch interface provided in terminal device 1 and configured with a touch panel. In such a case, monitor 14 has a function as input unit 15, accepts a user's input operation, and outputs a result of the user's input operation to processor 11.

Monitor 14 may be implemented by, for example, a head mounted display (HMD) communicatively connected to terminal device 1 in a wired or wireless manner.

Input unit 15 accepts a user's input operation for a setting of a threshold value of the leakage electric field intensity, a designation of a measurement target object, or the like, and outputs the input operation to processor 11. Input unit 15 may be realized as the touch panel of monitor 14 described above. Input unit 15 may accept a voice input operation based on the user's voice.

Next, an internal configuration example of measurement unit 2 will be described. Measurement unit 2 measures a leakage electric field leaking from a measurement target object (for example, an electric wire, a switch, or an electrical/electronic apparatus) in a live wire (energized) state and a distance to the measurement target object. Measurement unit 2 is detachably attached to a predetermined position in terminal device 1. Measurement unit 2 may be attached to a helmet, a belt, or the like equipped by the user. A structure for attaching and detaching measurement unit 2 is not illustrated and description thereof will be omitted.

Measurement unit 2 includes communicator 20, processor 21, memory 22, electric field sensor 24, and distance sensor 25. In a case where a distance to a measurement target object is measured by camera 13 of terminal device 1, distance sensor 25 is not an essential constituent and may thus be omitted, or may be configured separately from measurement unit 2 instead of being integrated with measurement unit 2. Electric field sensor 24 may be configured separately from measurement unit 2 instead of being integrated with measurement unit 2. Each of electric field sensor 24 and distance sensor 25 may be configured separately instead of being integrated, and may be connected by wire by using each of a plurality of USB cables or each of a plurality of LAN cables.

Communicator 20 has a USB connector (not illustrated), and is communicatively connected to communicator 10 of terminal device 1 in a wired manner by using USB cable CB or a LAN cable (not illustrated). Communicator 20 transmits each measurement result measured by electric field sensor 24 and distance sensor 25 to communicator 10.

Communicator 10 may be wirelessly communicatively connected to communicator 20. The wireless communication referred to here is communication via, for example, short-range wireless communication such as Bluetooth (registered trademark) or NFC (registered trademark), or a wireless LAN such as Wifi (registered trademark).

Processor 21 is configured by using, for example, a CPU, a DSP, or an FPGA, and controls an operation of each constituent of measurement unit 2. Each constituent referred to here is, for example, signal processor 23. Processor 21 cooperates with memory 22 to perform various processes and control in an integrated manner. Specifically, processor 21 refers to a program and data stored in memory 22, and executes the program to realize a function of each constituent (for example, a function of converting a reception signal that is received by electric field sensor 24 into a signal indicating a leakage electric field intensity).

Memory 22 has, for example, a RAM as a work memory used when executing each process of processor 21, and a ROM storing a program and data defining an operation of processor 21. Data or information generated or acquired by processor 21 is temporarily stored in the RAM. A program defining an operation of processor 21 is written in the ROM.

Signal processor 23 receives a reception signal obtained by receiving a leakage electric field from electric field sensor 24. Signal processor 23 performs conversion into a signal indicating the leakage electric field intensity leaking from the measurement target object on the basis of the reception signal input from electric field sensor 24. Signal processor 23 outputs a signal indicating the converted leakage electric field intensity to communicator 20.

Electric field sensor 24 as an example of a first acquirer has, for example, a dipole antenna or one or a plurality of loop antennas, and is configured to be able to receive a signal of a leakage electric field in a frequency bandwidth of 50 Hz to 60 Hz. Electric field sensor 24 may be formed as a planar antenna. Electric field sensor 24 constantly receives a leakage electric field leaking from an energized object in a live wire (energized) state, and outputs a received reception signal to signal processor 23 of processor 21.

Distance sensor 25 as an example of a second acquirer is, for example, a monocular camera or a stereo camera. Distance sensor 25 has a function of executing image analysis on an acquired captured image and executing a so-called autofocus process of automatically focusing on a predetermined measurement target object captured in an imaging region. Distance sensor 25 executes the autofocus process on the measurement target object captured in the imaging region, and measures a distance to the measurement target object on the basis of a focal length when the measurement target object is in focus.

In a case where it is determined that a plurality of measurement target objects are captured in the imaging region, distance sensor 25 sequentially executes the autofocus process on each of the plurality of measurement target objects. Distance sensor 25 measures a distance to each of the plurality of measurement target objects on the basis of the focal length. In a case where the user has designated a measurement target object, distance sensor 25 executes the autofocus process on the designated measurement target object on the basis of a control signal transmitted from processor 11 of terminal device 1 to processor 21 of measurement unit 2.

Distance sensor 25 may be, for example, an ultrasonic wave sensor, a radar, or the like. In such a case, distance sensor 25 measures a distance to a measurement target object and a direction of the measurement target object by using ultrasonic waves, radar sensor, or the like, and outputs these measurement results to processor 21. Distance sensor 25 may measure the distance to the measurement target object and the direction of the measurement target object on the basis of the result of the image processing of camera 13. Consequently, distance sensor 25 can narrow down a measurement target object that is a generation source of the leakage electric field within a range in which a distance and a direction can be measured.

Distance sensor 25 does not have to be capable of highly accurate directional positioning. For example, distance sensor 25 may be capable of measuring which direction a measurement target object is located in among three directions (front, right side, left side) with respect to a measurable range. Directions in which distance sensor 25 can perform measurement are not limited to three directions, and may be, for example, five directions obtained by dividing a measurable range into five.

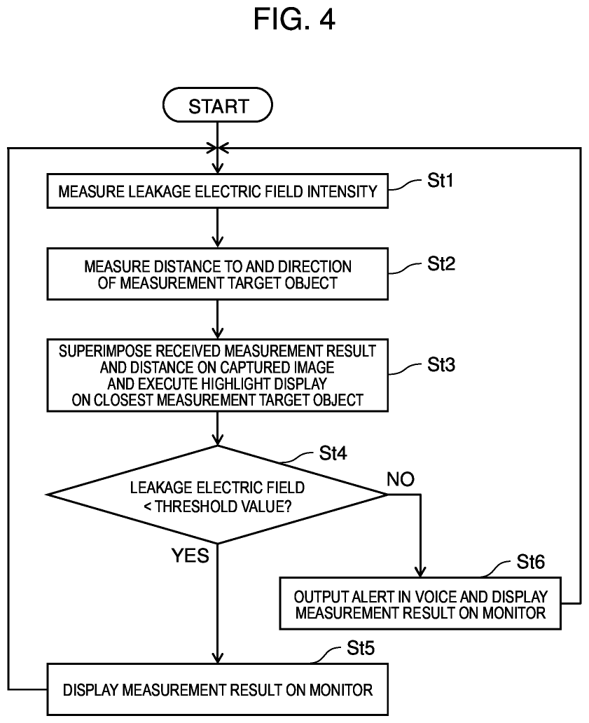

An operation procedure example of leakage electric field measurement device 100 according to Exemplary Embodiment 1 will be described with reference to FIG. 4. FIG. 4 is a flowchart illustrating an operation procedure example of leakage electric field measurement device 100 according to Exemplary Embodiment 1.

Electric field sensor 24 receives (measures) an electric field leaking from any of surrounding measurement target objects, and outputs a reception signal to signal processor 23 (St1). Signal processor 23 performs conversion into a signal indicating the leakage electric field intensity leaking from any of the measurement target objects on the basis of the reception signal received by electric field sensor 24. Signal processor 23 outputs a signal indicating the converted leakage electric field intensity to communicator 20. The output signal indicating the leakage electric field intensity is transmitted to processor 11 via communicator 20 and communicator 10. Processor 11 acquires the measurement electric field on the basis of the received and output signal indicating the leakage electric field intensity.

Distance sensor 25 measures a distance between each of the plurality of measurement target objects in a measurable range and a direction of each of the plurality of measurement target objects (St2). Distance sensor 25 outputs the measurement results to processor 21. The measurement results of the measured distance to and direction of each of the plurality of measurement target objects are transmitted to processor 11 via communicator 20 and communicator 10. In a case where a distance to each of a plurality of measurement target objects and a direction of each of a plurality of measurement target objects are measured by camera 13, camera 13 may execute image analysis on an acquired captured image to measure a distance to each of the plurality of analyzed measurement target objects and a direction of each of the plurality of measurement target objects.

Processor 11 estimates positions of the measurement target objects captured in the captured image on the basis of the respective received directions of the plurality of measurement target objects and the captured image acquired by camera 13, and superimposes frame lines at the positions. Processor 11 generates a composite image in which a measurement electric field as a measurement result of the received leakage electric field intensity and the distance information to each of the plurality of measurement target objects indicated by frame lines Are superimposed on the captured image. Processor 11 generates a composite image in which a frame line indicating a measurement target object located at the shortest distance among the pieces of distance information to the plurality of respective measurement target objects is highlighted (emphasized) and displayed (St3). Processor 11 may generate a composite image in which not only the frame line but also the distance information is similarly highlighted (emphasized) and displayed.

Processor 11 determines whether or not the received (measured) measurement electric field is below a set threshold value (St4).

In the process in step St4, in a case where the received (measured) measurement electric field is below the set threshold value (St4, YES), processor 11 outputs the generated composite image to monitor 14 and displays the composite image without further processes (St5).

On the other hand, in the process in step St4, in a case where the received (measured) measurement electric field is equal to or more than the set threshold value (St4, NO), processor 11 outputs the generated composite image to monitor 14 and displays the composite image without further processes, generates an alert for notifying that the measured measurement electric field exceeds the set threshold value (that is, there is an energized object that emits a high leakage electric field within an angle of view of camera 13), and outputs the alert from monitor 14 in voice (St6).

Consequently, leakage electric field measurement device 100 can visualize a direction in which the leakage electric field is generated. In a case where the received (measured) measurement electric field is equal to or more than the set threshold value, leakage electric field measurement device 100 may notify the user of the distance to the energized object that emits a high leakage electric field and the position thereof.

The operation procedure example illustrated in FIG. 4 is an example and the present disclosure is not limited to this. For example, the procedure of the process executed in step St1 and the procedure of the process executed in step St2 may be in the reverse order.

In the composite image generated in the process in step St3, the frame line indicating the position of the measurement target object may be omitted. In such a case, the composite image is generated such that a leakage electric field value and a distance are superimposed at a position near a measurement target object to which a measured distance is shortest and a distance measured is superimposed at a position near each of other measurement target objects on the captured image. The composite image may be generated such that the leakage electric field value and the distance are superimposed only at the position near the measurement target object to which a measured distance is shortest. Consequently, the user can check the position of the measurement target object on the basis of the position on which the leakage electric field value (numerical value) or the distance information is superimposed, and check the leakage electric field value leaking from the measurement target object or the distance to the measurement target object.

FIG. 5A is a diagram illustrating a measurement example of a leakage electric field by measurement unit 2. FIG. 5A illustrates superimposition image Sc 1 generated by processor 11 and superimposed on a captured image on the basis of respective measurement results measured by electric field sensor 24 and distance sensor 25.

Superimposition image Sc1 is generated to include measurement electric field Rs1, plurality of frame lines Ar1, Ar2, Ar3, and Ar4, and plurality of pieces of distance information M1, M2, M3, and M4. Although a plurality of frame lines and pieces of distance information are illustrated in FIG. 5A, each thereof may be used alone.

Measurement electric field Rs1 is a measurement result of the leakage electric field intensity measured (received) by electric field sensor 24. Measurement electric field Rs1 is displayed such as “measurement electric field: 2000 V/m” at a predetermined position in superimposition image Sc1. Displayed measurement electric field Rs1 is updated according to a measurement electric field measured (received) by electric field sensor 24, and the latest measurement result (that is, a measurement electric field) is always displayed.

Each of the plurality of frame lines Ar1 to Ar4 indicates the position of each of the plurality of measurement target objects. Each of plurality of frame lines Ar1 to Ar4 is displayed to include a part of each of a plurality of measurement target objects. Plurality of frame lines Ar1 to Ar4 illustrated in FIG. 5A substantially have the same size, but are not limited to this, and may be displayed in an enlarged or reduced size according to, for example, corresponding distance information.

Among plurality of frame lines Ar1 to Ar4, a frame line corresponding to a measurement target object located at the shortest distance is highlighted (emphasized) and displayed by processor 11. For example, frame line Ar2 illustrated in FIG. 5A indicates a position of the measurement target object located at the shortest distance among plurality of frame lines Ar1 to Ar4, and is displayed as a red frame line. Each of the other plurality of frame lines Ar1, Ar3, and Ar4 may be displayed as a frame line such as a blue or black line, or may be displayed as a frame line having a color and a thickness according to a distance.

Each of plurality of pieces of distance information M1 to M4 indicates a distance to each of the plurality of measurement target objects. Each of plurality of pieces of distance information M1 to M4 is not essential and thus does not have to be displayed. Each of plurality of pieces of distance information M1 to M4 illustrated in FIG. 5A is displayed to be surrounded by the frame line as an example, but the present disclosure is not limited thereto. For example, plurality of pieces of distance information M1 to M4 may be respectively displayed only by numbers (specifically, “1 m”, “0.7 m”, “2.2 m”, and “5 m”).

The shortest distance information among plurality of pieces of distance information M1 to M4 may be highlighted (emphasized) and displayed by processor 11. For example, among plurality of pieces of distance information M1 to M4, distance information M2 illustrated in FIG. 5A indicates a distance to a measurement target object located at the shortest distance and is displayed with a red frame line. Each of other plurality of pieces of distance information M1, M3, and M4 may be respectively displayed with a frame line such as a blue or black line, or may be displayed with a frame line having a color and a thickness according to a distance.

Processor 11 superimposes the above superimposition image Sc1 on the captured image acquired by camera 13 to generate composite image Sc2. Generated composite image Sc2 will be described with reference to FIG. 5B.

FIG. 5B is a diagram illustrating a display example of composite image Sc2. FIG. 5B illustrates an example of composite image Sc2 displayed on monitor 14. Composite image Sc2 illustrated in FIG. 5B is generated by superimposing superimposition image Sc1 described with reference to FIG. 5A on the captured image acquired by camera 13. Therefore, in composite image Sc2 illustrated in FIG. 5B, the same reference numerals are given to the constituents described in FIG. 5A, and the description thereof will be omitted.

Composite image Sc2 is generated to include measurement electric field Rs1, plurality of frame lines Ar1, Ar2, Ar3, and Ar4, plurality of pieces of distance information M1, M2, M3, and M4, and plurality of measurement target objects Tg1, Tg2, Tg3, and Tg4. Although a plurality of frame lines, pieces of distance information, and measurement target objects are illustrated in FIG. 5B, each thereof may be used alone.

Each of plurality of measurement target objects Tg1 to Tg4 is in a live wire (energized) state of, for example, an electric wire, a switch, or an electrical/electronic apparatus, and is a generation source of a leakage electric field.

When superimposition image Sc1 is superimposed on the captured image, processor 11 may execute the superimposition after aligning positions of plurality of frame lines Ar1 to Ar4 in superimposition image Sc1 with respective corresponding positions of plurality of measurement target objects Tg1 to Tg4.

In a case where plurality of pieces of distance information M1 to M4 are superimposed at the positions near the corresponding measurement target objects and measurement electric field Rs1 is superimposed at the position near the measurement target object located at the shortest distance, plurality of frame lines Ar1 to Ar4 may be omitted. Consequently, the user can check the position of the measurement target object on the basis of the position on which the leakage electric field value (numerical value) or the distance information is superimposed, and check the leakage electric field value leaking from the measurement target object or the distance to the measurement target object.

As described above, leakage electric field measurement device 100 according to Exemplary Embodiment 1 can visualize a direction in which a leakage electric field is generated.

### Exemplary Embodiment 2

In leakage electric field measurement device 100 according to Exemplary Embodiment 1, a configuration example in which terminal device 1 and measurement unit 2 are separately provided has been described. In leakage electric field measurement device 200 according to Exemplary Embodiment 2, a configuration example in which terminal device 1 and measurement unit 2 are integrally provided will be described.

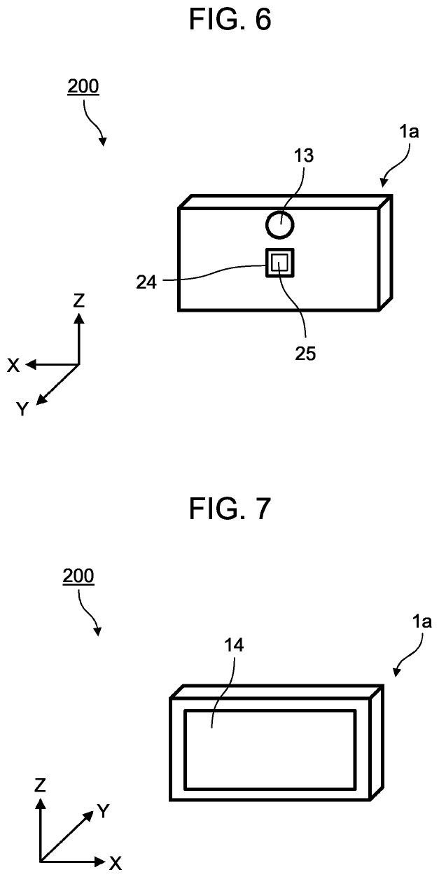

FIG. 6 is an appearance diagram illustrating an example of leakage electric field measurement device 200 (rear surface) according to Exemplary Embodiment 2. FIG. 7 is an appearance diagram illustrating an example of leakage electric field measurement device 200 (front surface) according to Exemplary Embodiment 2. Leakage electric field measurement device 200 according to Exemplary Embodiment 2 has substantially the same configuration as the configuration of leakage electric field measurement device 100 according to Exemplary Embodiment 1. Therefore, the same reference numerals are given to the same constituents as those in Exemplary Embodiment 1, and the description thereof will be omitted.

Leakage electric field measurement device 200 includes electric field sensor 24 and distance sensor 25 on the rear surface side of terminal device 1a. On the rear surface of leakage electric field measurement device 200, an optical axis of camera 13, a central axis of a measurement range in which an intensity of a leakage electric field can be measured by electric field sensor 24, and an optical axis of distance sensor 25 are disposed to be arranged in parallel to each other. Here, the central axis of electric field sensor 24 is perpendicular to the rear surface of terminal device 1a. In a case where camera 13 measures a distance to a measurement target object, distance sensor 25 may be omitted.

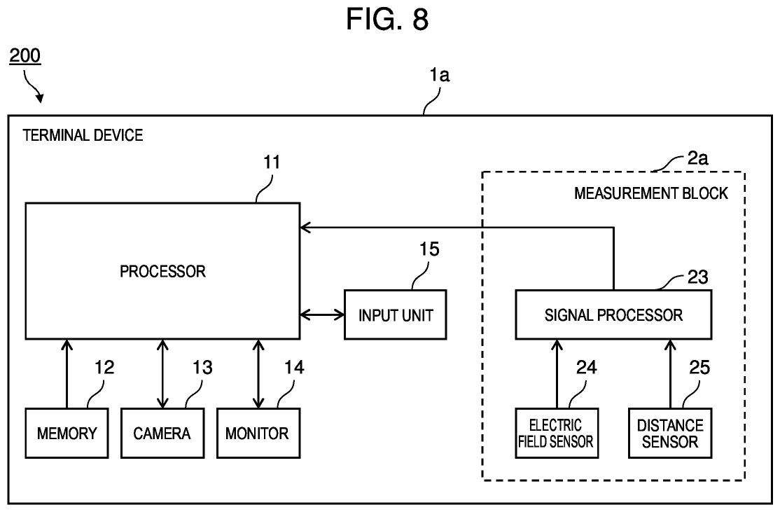

Consequently, an amount of misalignment (that is, an offset amount) between reference points in a captured image acquired by camera 13 and each of measurement results measured by electric field sensor 24 and distance sensor 25 is quantitatively reduced. Leakage electric field measurement device 200 can minimize an offset amount between camera 13 and electric field sensor 24 and an offset amount between camera 13 and distance sensor 25. Therefore, leakage electric field measurement device 200 can easily perform position alignment when the measurement results measured by electric field sensor 24 and distance sensor 25 are superimposed on the captured image acquired by camera 13. FIG. 8 is a block diagram illustrating an internal configuration example of leakage electric field measurement device 200 according to Exemplary Embodiment 2.

Measurement block 2a in Exemplary Embodiment 2 has substantially the same configuration as the internal configuration of measurement unit 2 in Exemplary Embodiment 1. Measurement block 2a is configured to include signal processor 23, electric field sensor 24, and distance sensor 25. A function of signal processor 23 may be realized by processor 11. Distance sensor 25 is not an essential constituent and may thus be omitted. In such a case, a function of distance sensor 25 may be realized by camera 13.

Processor 11 in Exemplary Embodiment 2 controls operations of terminal device 1a and each constituent of measurement block 2a provided in terminal device 1a. Processor 11 cooperates with memory 12 to perform various processes and control including measurement block 2a in an integrated manner. Specifically, processor 11 refers to a program and data stored in memory 12 and executes the program to realize a function of each constituent (for example, a function of measuring a leakage electric field with electric field sensor 24, a function of measuring a distance to a measurement target object and a direction of the measurement target object with distance sensor 25, a function of determining whether or not a measured measurement electric field exceeds a set threshold value, and a function of outputting a composite image in which a measurement result is superimposed on a captured image from camera 13 to monitor 14).

Memory 12 in Exemplary Embodiment 2 stores, for example, a set threshold value of a measurement electric field, emphasis and display methods, and an offset amount based on an imaging region of camera 13, a measurable range of electric field sensor 24, and a reference position for measurement of distance sensor 25.

As described above, leakage electric field measurement device 200 according to Exemplary Embodiment 2 is formed as an integral body and can visualize a direction in which a leakage electric field is generated.

As described above, leakage electric field measurement devices 100 and 200 according to Exemplary Embodiments 1 and 2 include a controller that generates a composite image in which a measurement result of an intensity of an leakage electric field measured by a first acquirer that measures intensity of the leakage electric field and a measurement location (frame line) corresponding to the shortest distance measured by a second acquirer that measures a distance to a target object (measurement target object) are superimposed on a captured image acquired by the first acquirer that captures the image of the target object.

Consequently, leakage electric field measurement devices 100 and 200 can generate the composite image in which an intensity of a surrounding leakage electric field measured by the first acquirer and a position of the measurement target object that may be a generation source of the leakage electric field are superimposed on the captured image acquired by the third acquirer and a position of the measurement target object located at the shortest distance to a user is visualized. Therefore, leakage electric field measurement devices 100 and 200 can visualize a direction of a target object (measurement target object) from which the leakage electric field is estimated to be generated to the user. Therefore, the user can easily know the direction of the generation source of the leakage electric field.

The controller in leakage electric field measurement devices 100 and 200 according to Exemplary Embodiments 1 and 2 performs a process of emphasizing a measurement location corresponding to the shortest distance in a case where there are a plurality of target objects (measurement target objects) measured by the second acquirer. Consequently, leakage electric field measurement devices 100 and 200 can emphasize and visualize a position of a target object (measurement target object) captured in the acquired captured image. Therefore, the user can easily know the direction of the generation source of the leakage electric field.

Leakage electric field measurement devices 100 and 200 according to Exemplary Embodiments 1 and 2 further include an output unit that outputs the composite image, and the controller outputs the generated composite image to the output unit. Consequently, leakage electric field measurement devices 100 and 200 can output the generated composite image to the output unit capable of outputting the composite image. Therefore, the user can check the direction of the generation source of the leakage electric field from the output composite image.

In leakage electric field measurement devices 100 and 200 according to Exemplary Embodiments 1 and 2, the first acquirer receives a signal with 50 Hz to 60 Hz. The leakage electric field at a frequency of 50 Hz to 60 Hz is highly distance-dependent. Therefore, leakage electric field measurement devices 100 and 200 can measure the intensity of the leakage electric field generated around the user with the first acquirer, and measure the distance to the measurement target object that may be a generation source of the leakage electric field with the second acquirer. Therefore, leakage electric field measurement devices 100 and 200 generate the composite image in which a measurement location (frame line) corresponding to the shortest distances among the measured distances is subjected to the emphasis process, and thus it is possible to visualize a direction of a measurement target object that may generate the leakage electric field and is located at the shortest distance to the user.

The second acquirer of leakage electric field measurement devices 100 and 200 according to Exemplary Embodiments 1 and 2 executes an autofocus process on the target object (measurement target object) captured in the captured image, and measures a distance to the target object (measurement target object) on the basis of a focal length during the autofocus process. Consequently, leakage electric field measurement devices 100 and 200 can measure the distance to the target object (measurement target object), and visualize a direction of the measurement target object that may generate the leakage electric field and is located at the shortest distance.

The controller of leakage electric field measurement devices 100 and 200 according to Exemplary Embodiments 1 and 2 changes a color of an outer frame (frame line) indicating a range of the measurement location as the emphasis process on the measurement location corresponding to the shortest distance on the basis of whether or not the measurement result of the measured leakage electric field intensity is equal to or more than a preset threshold value. Consequently, leakage electric field measurement devices 100 and 200 can visualize whether or not the measured leakage electric field intensity is equal to or more than the set threshold value by using colors. The user can easily determine whether or not the intensity of the leakage electric field generated in the surroundings is equal to or more than the threshold value according to the color of the outer frame (frame line) indicating the range of the measurement location.

The controller of leakage electric field measurement devices 100 and 200 according to Exemplary Embodiments 1 and 2 changes a size of the outer frame indicating the range of the measurement location acquired by the second acquirer to a size corresponding to the measured distance. Consequently, leakage electric field measurement devices 100 and 200 can visualize the distance to the measurement target object by using the size of the outer frame.

The controller of leakage electric field measurement devices 100 and 200 according to Exemplary Embodiments 1 and 2 superimposes the measurement location corresponding to the distance measured by the second acquirer at a position of the target object (measurement target object) captured in the captured image to generate the composite image. Consequently, leakage electric field measurement devices 100 and 200 can visualize the position of the measurement target object captured in the captured image. Therefore, the user can easily know the direction of the measurement target object to be moved away.

The controller of leakage electric field measurement devices 100 and 200 according to Exemplary Embodiments 1 and 2 generates the composite image in which the measurement result of the distance measured by the second acquirer is also superimposed. Consequently, leakage electric field measurement devices 100 and 200 can generate and visualize the composite image including not only the direction and position of the measurement target object but also the distance thereto.

In leakage electric field measurement devices 100 and 200 according to Exemplary Embodiments 1 and 2, an optical axis of the second acquirer and an optical axis of the third acquirer are disposed to be arranged in parallel to each other. Consequently, leakage electric field measurement devices 100 and 200 can minimize an offset amount between the third acquirer and the second acquirer, and quantitatively reduce an amount of misalignment (that is, an offset amount) in a reference point with the measurement result measured by the second acquirer.

The target object (measurement target object) in leakage electric field measurement devices 100 and 200 according to Exemplary Embodiments 1 and 2 is a conductor to which an AC voltage having a frequency of 50 Hz to 60 Hz is applied. A leakage electric field leaking from the conductor to which the AC voltage having a frequency of 50 Hz to 60 Hz is applied is highly distance-dependent. Therefore, leakage electric field measurement devices 100 and 200 can measure the intensity of the leakage electric field generated around the user with the first acquirer, and measure the distance to the measurement target object that may be a generation source of the leakage electric field with the second acquirer. Therefore, leakage electric field measurement devices 100 and 200 generate the composite image in which a measurement location (frame line) corresponding to the shortest distances among the measured distances is subjected to the emphasis process, and thus it is possible to visualize a direction of a measurement target object that may generate the leakage electric field and is located at the shortest distance to the user.

Although various exemplary embodiments have been described above with reference to the accompanying drawings, the present disclosure is not limited to such examples. It is obvious that a person skilled in the art can conceive of various changes, modifications, replacements, additions, deletions, and equivalents within the category disclosed in the claims, and it is understood that they fall within the technical scope of the present disclosure. The respective constituents in the various exemplary embodiments described above may be freely combined within the scope without departing from the concept of the invention.

### INDUSTRIAL APPLICABILITY

The present disclosure is useful as a leakage electric field measurement device visualizing a direction in which a leakage electric field is generated.

### REFERENCE MARKS IN THE DRAWINGS

1,1a Terminal device

2 Measurement unit

2a Measurement block

10, 20 Communicator

11, 21 Processor

12, 22 Memory

13 Camera

14 Monitor

15 Input unit

23 Signal processor

24 Electric field sensor

25 Distance sensor

100,200 Leakage electric field measurement device

Ar1, Ar2, Ar3, Ar4 Frame line

M1, M2, M3, M4 Distance information

Sc1 Superimposition image

Sc2 Composite image

Tg1, Tg2, Tg3, Tg4 Measurement target object

1. A leakage electric field measurement device comprising:
a first acquirer that measures an intensity of a leakage electric field;
a second acquirer that measures a distance to at least one target object;
a third acquirer that acquires a captured image of the at least one target object; and
a controller that generates a composite image in which a measurement result of the intensity of the leakage electric field measured by the first acquirer and a measurement location corresponding to a shortest distance among distances measured by the second acquirer are superimposed on the captured image acquired by the third acquirer.

2. The leakage electric field measurement device according to claim 1, wherein, in a case where the at least one target object measured by the second acquirer is plural, the controller executes an emphasis process on the measurement location corresponding to the shortest distance.

3. The leakage electric field measurement device according to claim 1, further comprising an output unit that outputs the composite image,
wherein the controller outputs the composite image to the output unit.

4. The leakage electric field measurement device according to claim 1, wherein the first acquirer receives a signal with 50 Hz to 60 Hz.

5. The leakage electric field measurement device according to claim 1, wherein the second acquirer executes an autofocus process on the at least one target object and measures the distance on the basis of a focal length during the autofocus process.

6. The leakage electric field measurement device according to claim 1, wherein the controller changes a color of an outer frame indicating a range of the measurement location as the emphasis process on the measurement location corresponding to the shortest distance on the basis of whether or not the measurement result of the measured intensity of the leakage electric field is equal to or more than a preset threshold value.

7. The leakage electric field measurement device according to claim 1, wherein the controller changes a size of an outer frame indicating a range of the measurement location to a size corresponding to the distance.

8. The leakage electric field measurement device according to claim 1, wherein the controller superimposes the measurement location at a position of the at least one target object captured in the captured image to generate the composite image.

9. The leakage electric field measurement device according to claim 1, wherein the controller generates the composite image in which a measurement result of the distance measured by the second acquirer is superimposed on the captured image.

10. The leakage electric field measurement device according to claim 1, wherein an optical axis of the second acquirer and an optical axis of the third acquirer are disposed to be arranged in parallel to each other.

11. The leakage electric field measurement device according to claim 1, wherein the at least one target object is a conductor to which an AC voltage having a frequency of 50 Hz to 60 Hz is applied.
